(19) United States
(12) Patent Application Publication
(10) Pub. No.: US 2026/0284711 A1
(43) Pub. Date: Sep. 24, 2026

(54) CLEANING APPARATUS AND CLEANING METHOD

(71) Applicant: SCREEN Holdings Co., Ltd., Kyoto (JP)

(72) Inventor: Takeshi SAIMYOJI, Kyoto-shi (JP)

(21) Appl. No.: 19/545,135

(22) Filed: Feb. 20, 2026

(30) Foreign Application Priority Data
Mar. 19, 2025 (JP) 2025-044342

(51) Int. Cl. B08B 3/02; B08B 13/00; H10P 72/00

(52) U.S. Cl. CPC B08B 3/02; B08B 13/00; H10P 72/0414

(57) ABSTRACT

This invention relates to a cleaning apparatus for cleaning a work including a plurality of chips arrayed on a surface of a sheet-like carrier with gap formed therebetween. The cleaning apparatus includes: a holder which holds the work in such a posture that principal surfaces of the chips are inclined with respect to a horizontal plane; a positioning mechanism which positions the work in a predetermined posture by rotating the work held by the holder about an axis of rotation along a normal direction to the principal surfaces; and a nozzle which is arranged above the work and discharges a cleaning liquid toward the work. Thus, the work can be effectively cleaned.

### CROSS REFERENCE TO RELATED APPLICATION

The disclosure of Japanese Patent Application No.2025-044342 filed on March 19, 2025 including specification, drawings and claims is incorporated herein by reference in its entirety.

### BACKGROUND OF THE INVENTION

### 1. Field of the Invention

This invention relates to a technique for cleaning a work in which diced semiconductor chips, for example, are carried on a sheet-like carrier.

### 2. Description of the Related Art

A semiconductor device manufacturing process includes a dicing step of dicing individual chips (dice) from a semiconductor wafer formed with a plurality of devices. Separation between the chips is performed by adhering the wafer to a stretchable sheet-like carrier and stretching the carrier to form gaps between the chips (expand processing). Since particles such as shavings may enter the gaps (grooves) formed in this way, cleaning is necessary.

For example, in a technique described in JP 2023-178867A (patent literature 1), a work is cleaned by a so-called spin cleaning method. In this method, a cleaning liquid is supplied to the upper surface of the work while the work held in a horizontal posture is rotated, and cleaning is performed by spreading the cleaning liquid to the entire work by a centrifugal force.

Since chips are generally laid out in a two-dimensional matrix on a wafer, grooves separating between the chips in a work are, for example, arranged in a two-dimensional lattice. On the other hand, in spin cleaning, a cleaning liquid supplied to the work radially flows from a center of rotation toward a peripheral edge by a centrifugal force. Thus, a sweeping action by the cleaning liquid does not necessarily sufficiently function for particles adhering to the insides of the grooves. Therefore, the spin cleaning in the above conventional technique has a problem that particles may remain inside the grooves and there is a room for improvement in more effectively performing cleaning.

### SUMMARY OF THE INVENTION

This invention was developed in view of the above problem and proposes a technique capable of effectively cleaning a work structured such that a plurality of chips are arrayed on a carrier while being spaced apart.

One aspect of the invention is directed to a cleaning apparatus for cleaning a work including a plurality of chips arrayed on a surface of a sheet-like carrier with gaps formed therebetween, the cleaning apparatus including a holder for holding the work in such a posture that principal surfaces of the chips are inclined with respect to a horizontal plane, a positioning mechanism for positioning the work in a predetermined posture by rotating the work held by the holder about an axis of rotation along a normal direction to the principal surfaces, and a nozzle arranged above the work, the nozzle discharging a cleaning liquid toward the work.

Further, another aspect of this invention is directed to a cleaning method for cleaning a work including a plurality of chips arrayed on a surface of a sheet-like carrier with gaps formed therebetween, the cleaning method including holding the work such that principal surfaces of the chips are inclined with respect to a horizontal plane and grooves between the chips formed in the gaps extend along a plane parallel to a normal direction to the principal surfaces and a vertical direction, arranging a nozzle above the work, and discharging a cleaning liquid from the nozzle toward the work.

In the invention thus configured, the cleaning liquid supplied to the work flows along a surface of the work held in an inclined state by the action of gravity. In the work, the grooves are formed in the gaps between the arrayed chips. Since the work is rotatable about the axis of rotation along the normal direction to the chip principal surfaces, the work can be so positioned that a flowing direction of the cleaning liquid on the work surface and an extension direction of the grooves coincide. If the cleaning liquid is discharged from the nozzle in such a positioned state, the cleaning liquid flows down along the grooves. Particles adhering to the grooves also flow down, together with the cleaning liquid, and are ejected. As a result, in the invention, the work structured such that the plurality of chips are arrayed on the carrier while being spaced apart can be effectively cleaned.

As described above, according to the invention, when the cleaning liquid discharged from the nozzle flows down along the work surface, a flow-down direction of the cleaning liquid and the direction of the grooves formed in the gaps between the chips can be made to coincide. Thus, the remaining of particles in the grooves can be suppressed and the work can be effectively cleaned.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIGS. 1A to 1C are diagrams schematically showing a configuration example of a work;

FIGS. 2A and 2B are diagrams showing one embodiment of a cleaning apparatus according to the invention;

FIG. 3 is a diagram showing a change in the rotation angle of the work;

FIGS. 4A and 4B are diagrams illustrating a discharge mode of the cleaning liquid from the nozzle;

FIGS. 5A and 5B are diagrams illustrating a discharge mode of the cleaning liquid from the nozzle; and

FIG. 6 is a flow chart showing the cleaning process in this embodiment.

### DETAILED DESCRIPTION OF THE PREFERRED EMBODIMENTS

Hereinafter, several embodiments of a cleaning apparatus according to the invention are described. Here, the work to be cleaned and the principle of the cleaning process are first described.

### Description of Work

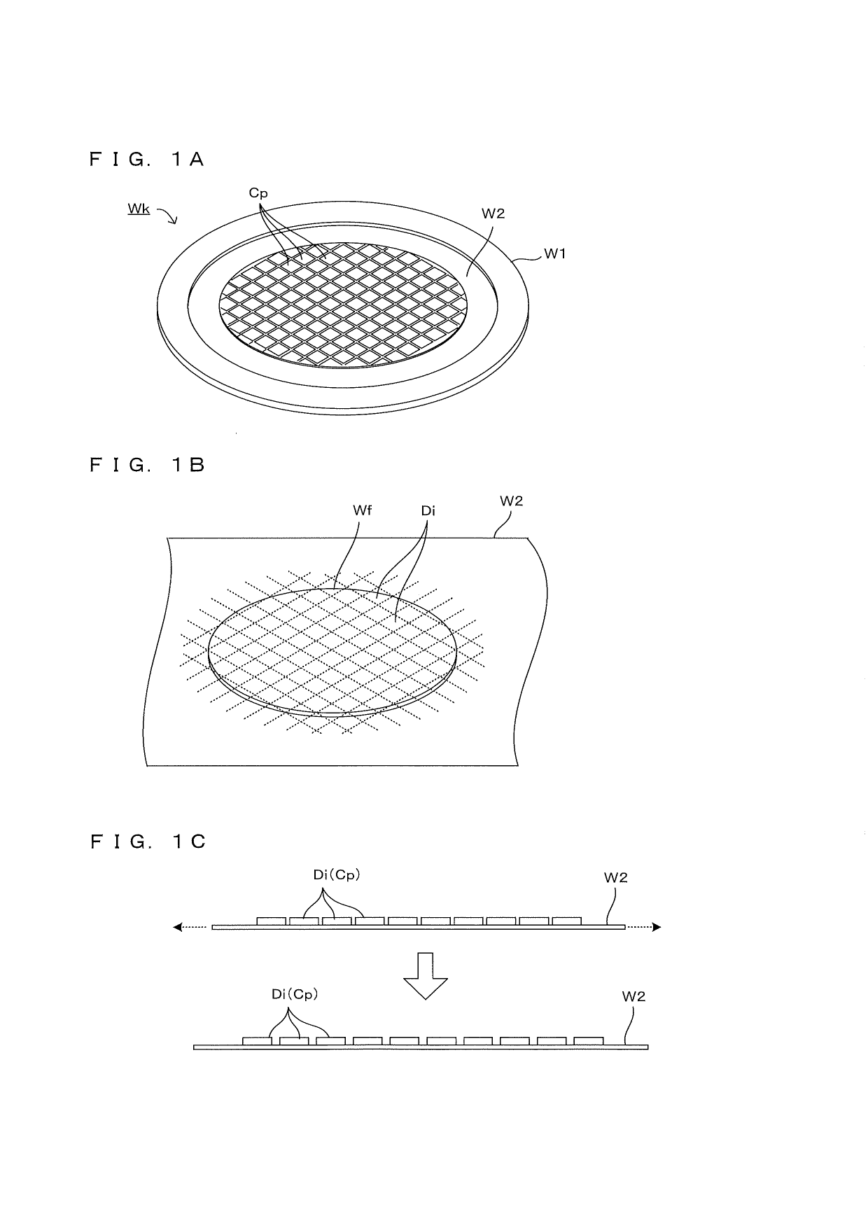

FIGS. 1A to 1C are diagrams schematically showing a configuration example of a work. More specifically, FIG. 1A is a diagram showing the external appearance of a work Wk, and FIG. 1B is a diagram schematically showing a dicing processing for a semiconductor wafer (hereinafter, a “wafer”) Wf. Further, FIG. 1C is a diagram schematically showing an expand processing for the diced wafer Wf.

As shown in FIG. 1A, the work Wk to be processed in an embodiment to be described later is configured such that a plurality of chips Cp diced from the wafer Wf are arrayed in a two-dimensional matrix on the upper surface of a sheet-like dicing tape W2 stretched in a hollow part of a flat ring-like dicing frame W1. Each chip Cp finally becomes a semiconductor device such as an integrated circuit.

Since the dicing processing of dicing the plurality of chips Cp collectively formed in the wafer Wf from the wafer Wf is known, it is briefly described here. As shown in FIG. 1B, the substantially disk-like wafer Wf is divided into a plurality of dice Di along cutting lines shown by dotting lines, for example, by a cutting means such as a diamond blade or a laser cutter.

At this time, to prevent the separated dice Di from scattering, the wafer Wf is mounted on the dicing tape W2. That is, the dicing tape W2 is adhered to the underside of the wafer Wf in advance. The dicing tape W2 is a stretchable sheet-like material, for example, made of resin, and adheres to and holds the wafer Wf by an adhesive applied to a surface. The dicing tape is also called a DAF (Die Attach Film).

After wafer cutting, the dicing tape W2 is stretched outward in surface directions (expand processing) as shown in FIG. 1C. By doing so, intervals between the separated dice Di expand. As a result, each die Di (chip Cp) is easily removed from the dicing tape W2. Note that, here, small pieces separated from the wafer Wf are called the dice Di and, out of those, one formed with a circuit or the like and planned to function as a semiconductor device is called the chip Cp.

Since the dicing tape W2 is a flexible material, a peripheral edge part is fixed by the ring-shaped dicing frame W1 for easy handling. In this way, the work Wk is configured. Note that the work Wk to be cleaned may be either such that the intervals between the chips Cp after dicing and before expansion are relatively narrow or such that the intervals between the chips Cp after expansion are wide.

### Principle of Cleaning Process

In the work Wk configured as described above, the chips Cp are arrayed in a two-dimensional matrix and gaps are provided between the respective chips Cp. Thus, grooves are formed between adjacent ones of the chips Cp. When the respective chips Cp have a rectangular shape and are linearly arrayed, a chip array direction and an extension direction of the grooves formed between those chips intersect each other. On the other hand, if the chips Cp are two-dimensionally arrayed in two array directions, the grooves extending along each of those array directions are formed into a lattice.

Particles such as shavings produced by dicing enter these grooves, and a cleaning process for removing these is necessary. Here, in spin cleaning for supplying a cleaning liquid while rotating a work as in the conventional technique, a flow of the cleaning liquid radially occurring by a centrifugal force and the extension directions of the grooves between the chips do not necessarily coincide. Thus, side surfaces of the chips Cp serve as barriers and the ejection of the particles does not proceed, with the result that the particles remain in the grooves. This hinders an improvement in cleaning efficiency.

In view of this problem, in each embodiment to be described later, the work Wk is held in a state inclined from a horizontal posture and the posture of the work Wk is kept such that an extension direction of the grooves between the chips is made to coincide with a flow-down direction of the cleaning liquid. Accordingly, the cleaning liquid quickly flows down along the grooves and the stay thereof in the grooves is avoided. In this way, a flow of the cleaning liquid along the grooves is generated, the ejection of particles remaining in and adhering to the insides of the grooves is promoted, and a cleaning effect can be enhanced.

Note that the dicing frame W1, the dicing tape W2 and the dice Di (chips Cp) are integrated in the work Wk as described above, but, out of these, the dicing frame W1 and the dicing tape W2 are auxiliary tools for maintaining the postures of the dice Di. From this, in the following description, the work Wk may be shown as an aggregate of the dice Di (chips Cp) without the dicing frame W1 and the dicing tape W2.

### Configuration and Operation of Cleaning Apparatus

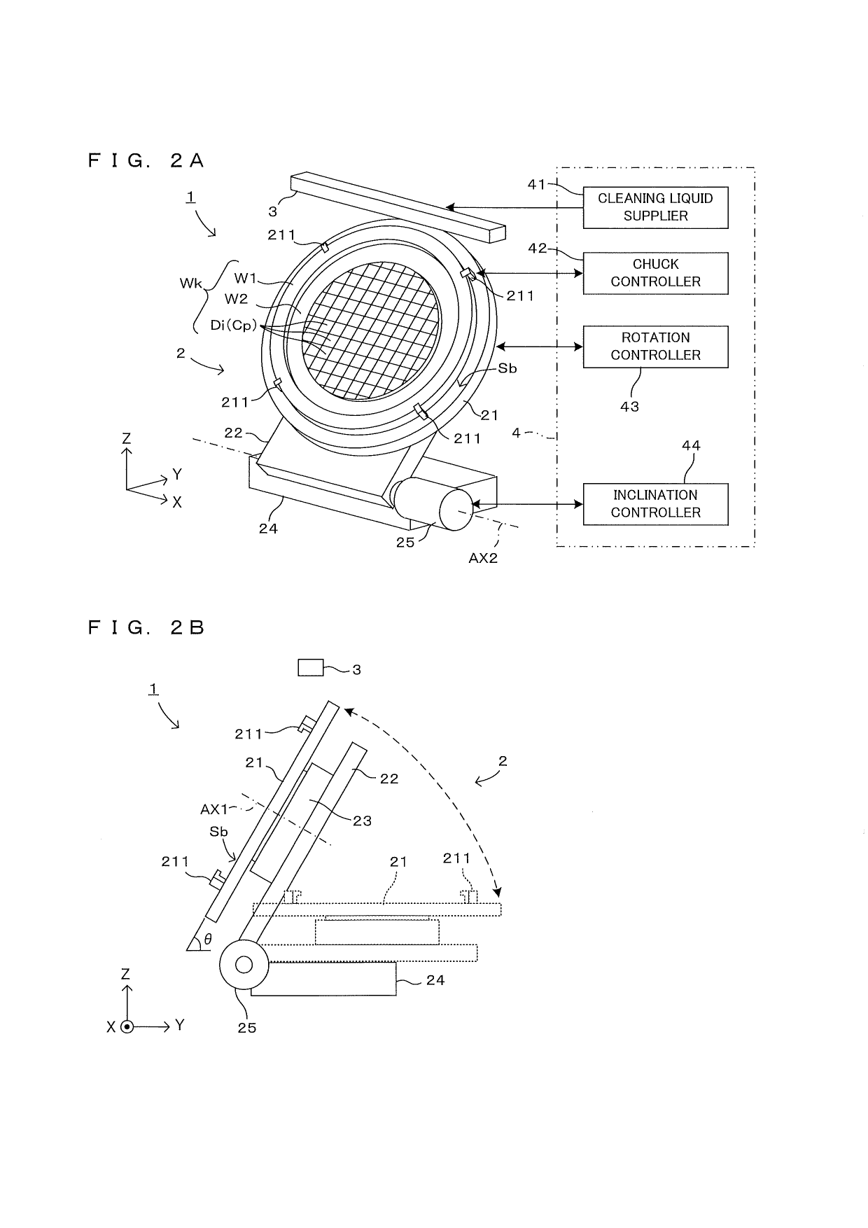

FIGS. 2A and 2B are diagrams showing one embodiment of a cleaning apparatus according to the invention. More specifically, FIG. 2A is a perspective view showing a main configuration of a cleaning apparatus 1 of this embodiment and FIG. 2B is a side view. Note that a state where the work Wk is held on the cleaning apparatus 1 is shown in FIG. 2A, whereas the work Wk is not shown in FIG. 2B. Here, an XYZ orthogonal coordinate system is introduced to show directions in the apparatus. This is a coordinate system in which an XY plane is a horizontal plane and a Z axis represents a vertical axis.

This cleaning apparatus 1 is provided with a work holding unit 2, a nozzle 3 and a control unit 4 as main components. The work holding unit 2 is provided with a work base 21 capable of holding the work Wk. That is, the work base 21 is a disk-like member slightly larger than a diameter of the work Wk, and chuck mechanisms 211 for fixing the work Wk are arranged on a principal surface Sb of the work base 21. In this example, four chuck mechanisms 211 are provided at equal angular intervals, but the number and positions thereof are not limited to these.

The chuck mechanisms 211 are controlled by a chuck controller 42 provided in the control unit 4. Specifically, each chuck mechanism 211 is switched to a holding state where the work Wk placed on the work base 21 is fixed and a releasing state where the fixed state is released in response to a control command from the chuck controller 42.

The work base 21 is rotatably mounted on an inclination plate 22. That is, an rotary actuator 23 is fixed to the flat plate-like inclination plate 22, and the work base 21 is mounted on the rotary actuator 23. The rotary actuator 23 has a rotation angle of 90° or more, desirably 180° or more. The rotary actuator 23 may be a rotary motor or the like configured to continuously rotate 360° or more.

The rotary actuator 23 is controlled by a rotation controller 43 of the control unit 4. Specifically, the rotary actuator 23 actuates in response to a control command from the rotation controller 43. Thus, the work base 21 rotates about an axis of rotation AX1 (shown by a one-dot chain line in FIG. 2B) orthogonal to the principal surface Sb. With the work Wk held on the work base 21, the axis of rotation AX1 is also orthogonal to the principal surfaces of the dicing tape W2 of the work Wk and the chips Cp.

The inclination plate 22 is pivotably supported by a base 24. Specifically, the inclination plate 22 is attached to the base 24 via an unillustrated appropriate hinge, and a rotary actuator 25 is coupled to the inclination plate 22. The rotary actuator 25 is controlled by an inclination controller 44 of the control unit 4. Specifically, the rotary actuator 25 actuates in response to a control command from the inclination controller 44, whereby the inclination plate 22 pivots about a pivot axis AX2 parallel to an X axis. As a result, as indicated by broken-like arrows in FIG. 2B, the posture of the inclination plate 22 changes between a horizontal posture shown by a dotted line and an inclined state shown by a solid line in FIG. 2B.

The work base 21 also changes between a state where the principal surface Sb thereof is horizontal and a state where the principal surface Sb is inclined, integrally with the inclination plate 22. A maximum angle of inclination θ of the principal surface Sb with respect to a horizontal plane can be, for example, an arbitrary value equal to or more than 45° and less than 90°. With the work Wk held on the work base 21, the dicing tape W2 and the chips Cp of the work Wk also change between the horizontal state and the inclined state.

As just described, the work Wk held on the work base 21 can change the posture from the horizontal posture to the inclined posture by the actuation of the rotary actuator 25 and change the rotation angle by the actuation of the rotary actuator 23.

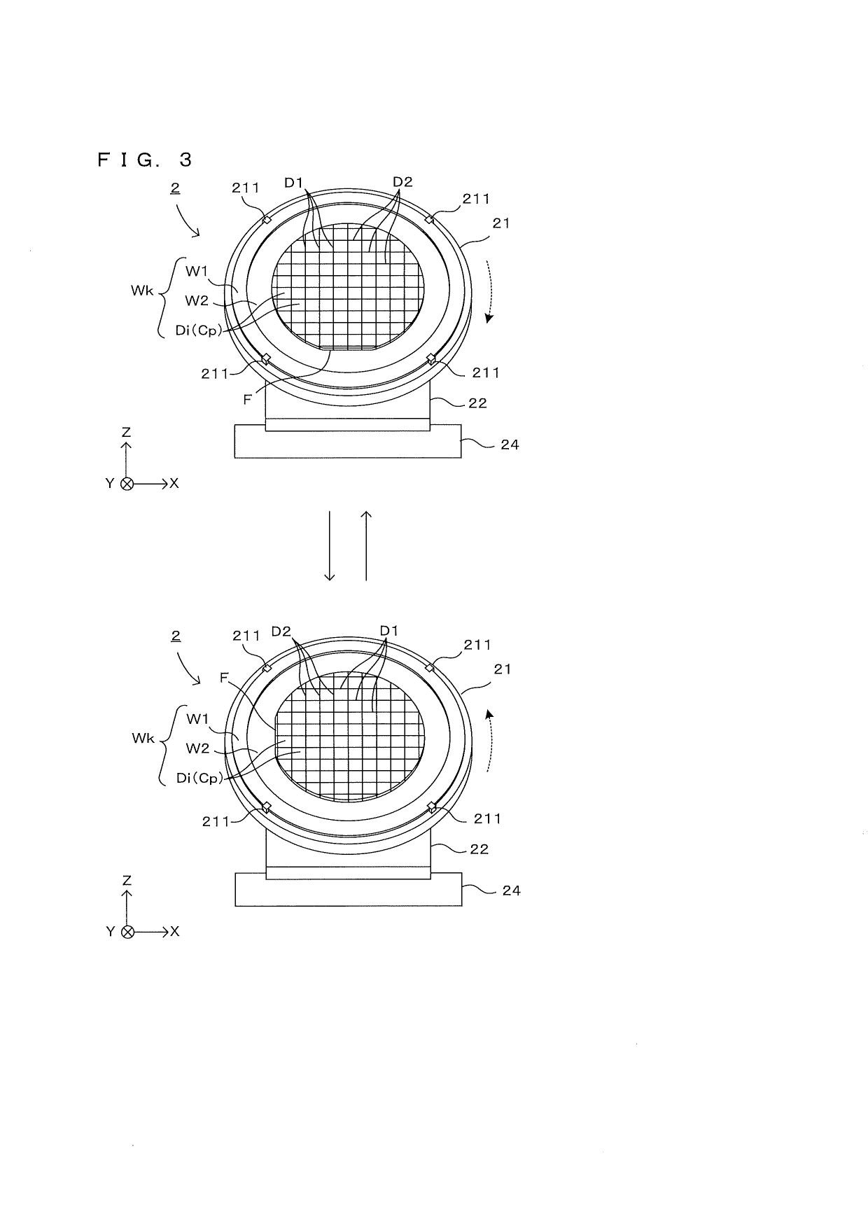

FIG. 3 is a diagram showing a change in the rotation angle of the work. Here, to clearly show the angle of the work Wk, it is assumed that the wafer Wf before dicing is provided with an orientation flat part F. As described above, the grooves are formed in the gaps between the two-dimensionally arrayed chips Cp in the work Wk after the dicing processing. As a specific example, it is assumed that there are grooves D1 orthogonal to the orientation flat part F and grooves D2 parallel to the orientation flat part F.

The rotary actuator 23 rotates the work base 21, whereby the posture of the work Wk changes between a first posture shown in an upper part of FIG. 3 and a second posture shown in a lower part of FIG. 3. Here, the first posture is such a posture that the grooves D1 orthogonal to the orientation flat part F extend in a vertical direction when the work Wk is viewed in a Y-axis direction. More strictly speaking, the work Wk is so positioned that a plane including both normal vectors to the respective chips Cp and a direction vector in a Z direction and a direction vector in an extension direction of the grooves D1 are parallel.

In other words, a roll-down or slide-down direction of objects in the grooves D1 by the action of gravity and the extension direction of the grooves D1 are the same. That is, particles adhering to the grooves D1 tend to fall down along the grooves D1 by the action of gravity if the work Wk is inclined.

On the other hand, the second posture corresponds to a state where the work base 21 is rotated by 90° from the first posture, and is such a posture that the grooves D2 parallel to the orientation flat part F extend in the vertical direction when the work Wk is viewed in the Y-axis direction. As just described, the first and second postures are so determined that the grooves D1, D2 in two directions orthogonal to each other in the work Wk respectively extend in the vertical direction when viewed in the Y-axis direction.

Referring back to FIG. 2A, the nozzle 3 for discharging the cleaning liquid is arranged above the work Wk held on the work base 21. The cleaning liquid having an appropriate composition is supplied to the nozzle 3 from a cleaning liquid supplier 41 of the control unit 4. The composition of the cleaning liquid is not particularly limited, but pure water or de-ionized water (DIW) can be, for example, used.

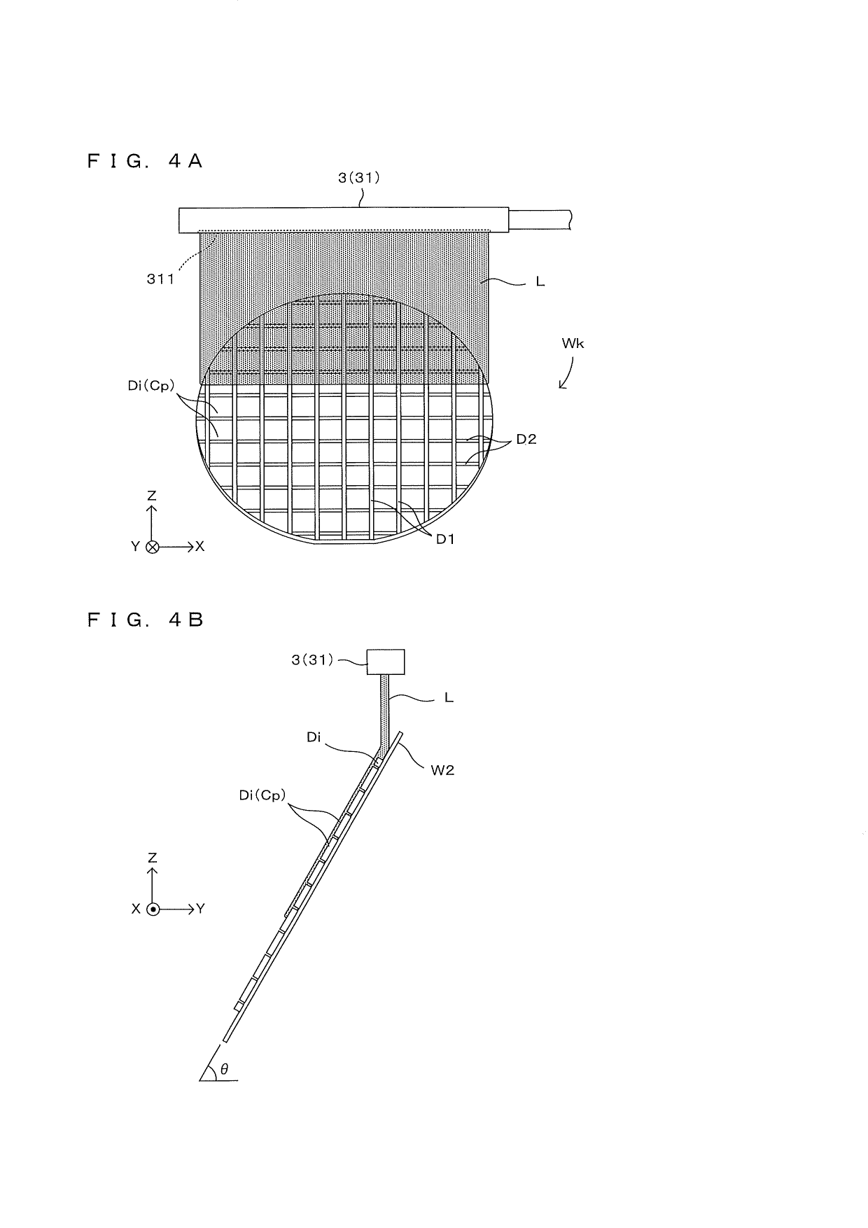

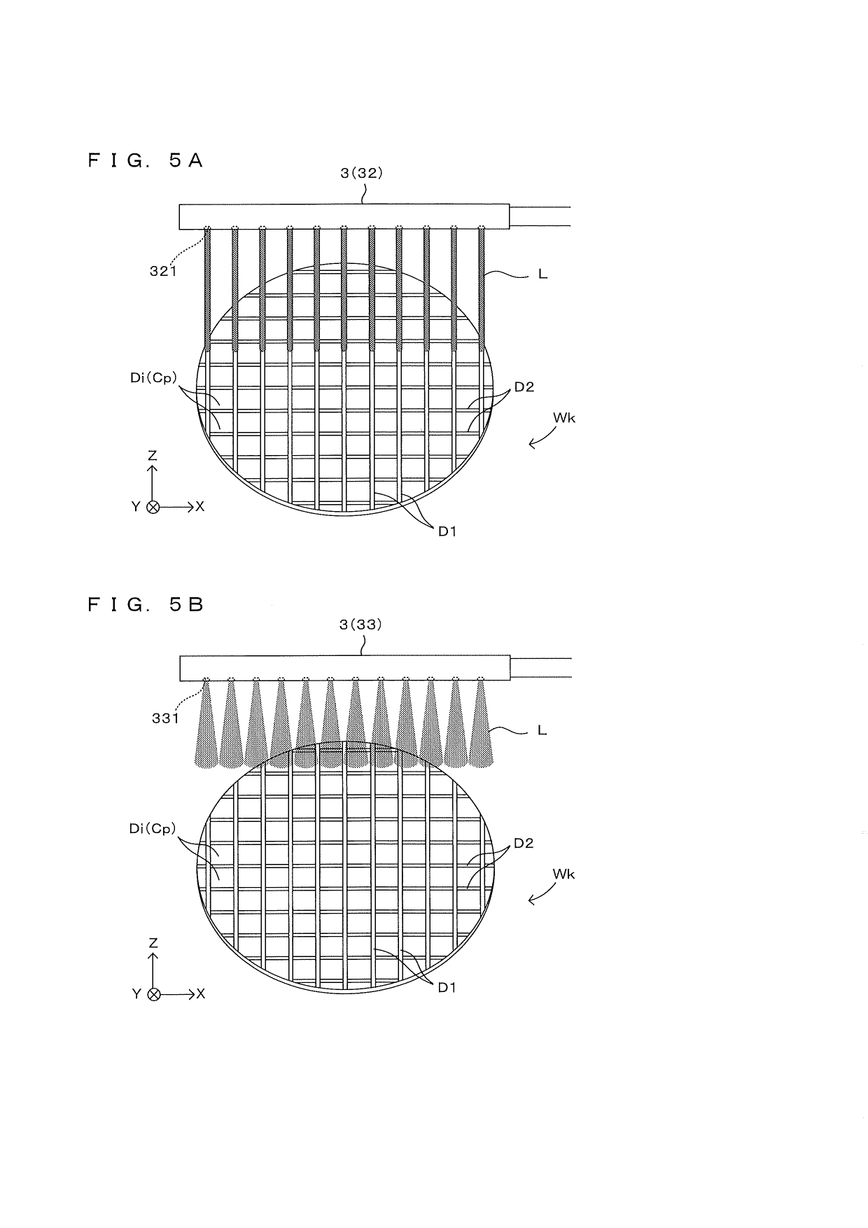

FIGS. 4A, 4B, 5A and 5B are diagrams illustrating a discharge mode of the cleaning liquid from the nozzle. Several variations are thought as discharge modes of the cleaning liquid. In an example shown in FIG. 4A, a slit-like discharge port 311 having a longitudinal direction in the X direction is provided in a lower part of a nozzle 3 (31). Accordingly, the cleaning liquid L is discharged from the nozzle 31 like a curtain wide in the X direction and narrow in the Y direction. An opening length of the discharge port 311 in the X direction is set to cover an entire distribution range of the dice Di in the X direction. Further, as shown in FIG. 4B, the position in the Y direction of the nozzle 31 is set to supply the cleaning liquid L also to the uppermost dice Di.

When the work Wk is positioned in the first posture, the cleaning liquid supplied to the work Wk flows down along the surfaces of the dice Di and the grooves D1. Since the flow-down direction of the cleaning liquid and the extension direction of the grooves D1 are the same, particles adhering to the grooves D1 can be effectively removed.

If the rotary actuator 23 rotates the work base 21 to position the work Wk in the second posture, the direction of the grooves D2 coincides with the flow-down direction of the cleaning liquid. At this time, particles adhering to the grooves D2 can be effectively removed. As just described, the work Wk is positioned to make the extension direction of the grooves and the flow-down direction of the cleaning liquid coincide and this is performed for the respective grooves in different directions, whereby those grooves can be effectively cleaned.

In an example shown in FIG. 5A, a plurality of discharge ports 321 are arranged side by side in the X direction in a lower part of a nozzle 3 (32) and array pitches thereof are the same as those of the grooves D1 in the work Wk. The nozzle 32 is positioned to align the positions of the grooves D1 and those of the discharge ports 321 in the X direction. In such a configuration, the cleaning liquid discharged from the respective discharge ports 321 directly lands the respective grooves D1 and directly flows down along the grooves D1. Thus, for the purpose of cleaning the grooves D1, a cleaning effect for the used amount of the cleaning liquid can be said to be highest.

However, the array pitches of the discharge ports need to be also changed if the size of the chips Cp formed in the wafer Wf is changed. Therefore, in terms of versatility capable of dealing with various chip sizes, the curtain-like discharge mode shown in FIG. 4A is advantageous.

In an example shown in FIG. 5B, a plurality of discharge ports 331 are arranged side by side in the X direction in a lower part of a nozzle 3 (33). The cleaning liquid is spray-discharged from the respective discharge ports 331. Also by such a mode, effects similar to those of the first example shown in FIG. 4A can be obtained. In the cleaning apparatus 1 of this embodiment, any of the modes described above may be adopted. Further, the cleaning liquid may be, for example, dripped without being limited to continuous flowing-down.

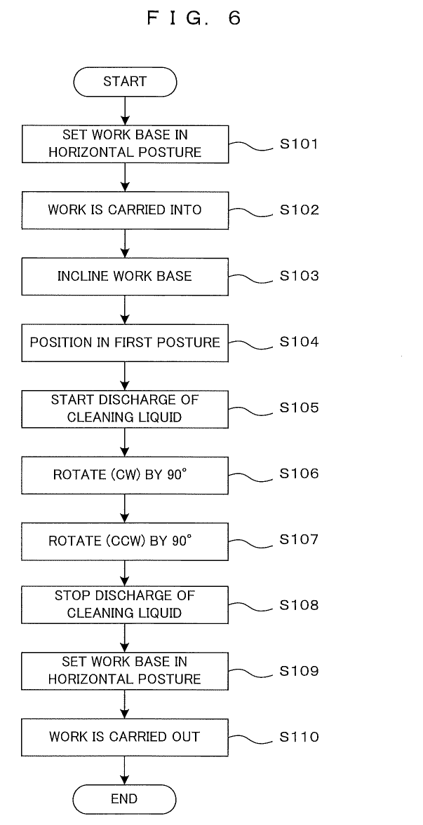

FIG. 6 is a flow chart showing the cleaning process in this embodiment. First, the work base 21 is set in the horizontal posture by the rotary actuator 25 (Step S101). The work Wk to be cleaned after the dicing processing or after the expand processing is carried into the cleaning apparatus 1 by an external conveyor apparatus (Step S102). The work Wk is placed in the horizontal posture on the work base 21 and fixed by the chuck mechanisms 22.

Further, the rotary actuator 25 actuates and inclines the work base 21 to a predetermined angle of rotation (Step S103). Subsequently, the rotary actuator 23 actuates and the work Wk is positioned in the first posture (FIG. 3A) (Step S104). Note that, if positioning has been achieved when the work Wk is placed on the work base 21, this step can be omitted.

If the work Wk is positioned at a predetermined position in this way, the discharge of the cleaning liquid from the nozzle 3 is started (Step S105). Since the work Wk is in the first posture, the cleaning liquid flows down along the grooves D1. After the elapse of a predetermined time, the work base 21 is rotated clockwise (CW) by 90° by the rotary actuator 23 (Step S106). In this way, the work Wk is switched to the second posture (FIG. 3B) and the cleaning liquid flows down along the grooves D2.

After the elapse of a predetermined time in this state, the work base 21 is rotated counterclockwise (CCW) by 90° (Step S107). In this way, the work Wk returns to the first posture. In this way, the grooves D1, D2 respectively extending in the different directions are cleaned. The switch between the first posture and the second posture may be repeated a plurality of times if necessary. In this case, the work base 21 may be rotated in one direction. That is, the work base 21 may be rotated in the same direction by 90° at each of a plurality of times.

Thereafter, the discharge of the cleaning liquid is stopped (Step S108) and the work base 21 is returned to the horizontal posture by the rotary actuator 25 (Step S109). Then, the work Wk is carried out (Step S110) and a series of processings are finished. If there is a work Wk to be successively processed, the above processings are repeated. Since the work base 21 is in the horizontal posture when the work Wk is carried out, Step S101 can be omitted.

In this embodiment, the discharge of the cleaning liquid is continued also while the posture of the work Wk is changed. In this way, an improvement in the cleaning effect for the surfaces of the chips Cp is expected, but the discharge of the cleaning liquid may be stopped during the posture switch for the purpose of cleaning the grooves D1, D2.

Further, in the above embodiment, the posture of the work base 21 is switched between the horizontal posture and the inclined posture by the rotary actuator 25. This is for convenience in carrying in and out the work. On the other hand, if the work Wk is transferrable to and from outside with the work base 21 inclined, the work base 21 may be kept in the inclined posture.

As described above, in this embodiment, the work Wk obtained by dicing (and expanding) the wafer Wf adhered to the dicing tape is cleaned. At this time, the cleaning liquid is supplied with the work Wk inclined and the work Wk is so positioned that the extension direction of the grooves formed between the arrayed chips coincides with the flow-down direction of the cleaning liquid. Thus, the cleaning liquid smoothly flows down along the grooves without staying. In this way, the particles adhering to the grooves can be efficiently ejected together with the cleaning liquid. As just described, in this embodiment, the work formed with the grooves between the array chips can be effectively cleaned.

### Miscellaneous

As described above, in each of the above embodiments, the cleaning apparatus 1 corresponds to a “cleaning apparatus” of the invention. The holder 2 and the nozzle 3 respectively function as a “holder” and a “nozzle” of the invention. Further, the rotary actuator 23 functions as a “positioning mechanism” of the invention. Further, in the holder 2, the work base 21, the chuck mechanisms 211 and the rotary actuator 25 respectively function as a “holding member”, a “chuck mechanism” and an “inclination adjusting mechanism” of the invention. Further, the dicing tape W2 corresponds to a “carrier” of the invention.

Note that the invention is not limited to the embodiments described above, and various changes can be made besides the aforementioned ones without departing from the gist of the invention. For example, although the dicing frame W1 is assumed to have a circular ring shape and the work base 21 is assumed to have a circular plate shape for the description of the principle in the description of each of the above embodiments, a dicing frame used in an actual manufacturing site has a more complicated shape as also disclosed in patent literature 1. Therefore, the shape of a work base can be appropriately changed according to the shape and structure of a dicing frame.

Further, in the above embodiments, the nozzle 3 having the longitudinal direction in the X direction is used to clean the plurality of grooves of the work Wk collectively, and a discharge range of the cleaning liquid also extends long in the X direction. However, in principle, the plurality of grooves may be cleaned one by one. That is, the entire work may be cleaned by scanning and moving a nozzle including a single discharge port in the X direction.

Further, for example, in the above embodiments, the fixing of the work Wk to the work base 21 is realized by the chuck mechanisms 22 for mechanically pressing the work Wk. However, a holding mode of the work Wk is arbitrary without being limited to this. For example, the work Wk can be held by providing a suction hole, to which a negative pressure is applied, in the upper surface of the work base and vacuum-suctioning the lower surface of the dicing frame W1 of the work Wk.

Further, for example, the cleaning process is performed using only one type of the cleaning liquid in the above embodiments, but a plurality of cleaning liquids such as a chemical solution and a rinse liquid may be, for example, used. In this case, after one groove or the work is entirely processed by one cleaning liquid, cleaning by another cleaning liquid may be performed.

As the specific embodiments have been illustrated and described above, the positioning mechanism is preferably configured to position the work such that grooves between chips formed in gaps extend along a plane parallel to the normal direction and a vertical direction in the cleaning apparatus according to the invention. By doing so, the cleaning liquid quickly flows down along the grooves without staying, wherefore the cleaning effect can be further enhanced.

Further, for example, in the case of cleaning a work including a plurality of chips two-dimensionally arrayed in two array directions intersecting each other, after the work is positioned in a first posture in which grooves formed along a first direction, out of the two array directions, extend along a plane, the work may be rotated and positioned in a second posture in which grooves formed along a second direction, out of the two array directions, extend along the plane, and a cleaning liquid may be discharged from a nozzle in each of a state where the work is positioned in the first posture and a state where the work is positioned in the second posture. By doing so, the excellent cleaning effect can be obtained for the respective grooves extending in the two different directions.

In this case, the nozzle may continuously discharge the cleaning liquid while the posture of the work is changed from the first posture to the second posture. For the purpose of cleaning the grooves, it is sufficient to supply the cleaning liquid in each of the first and second postures. However, if the cleaning liquid continues to be supplied also during that transition period, the cleaning effect can be provided not only for the insides of the grooves, but also for chip surfaces.

Further, the nozzle may be provided with a plurality of discharge ports respectively corresponding to the plurality of grooves. According to such a configuration, the cleaning liquid can be supplied to the plurality of respective grooves collectively, and a time required to clean the work can be shortened.

Further, a holder may include a holding member having a work placement surface on which the work is to be placed, a chuck mechanism for fixing the work to the work placement surface, and an inclination adjusting mechanism for displacing the holding member between a horizontal posture and an inclined posture. In carrying in and out the work, it is not easy to handle the work in an inclined state. If the holding member is configured to be able to change the posture between the horizontal posture and the inclined posture, an existing conveyor apparatus can be, for example, applied by setting the holding member in the horizontal posture when the work is carried in and out.

This invention is applicable to processes in general including a dicing step of separating a semiconductor wafer in units of chips, and particularly suitable for the purpose of cleaning a diced work.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A cleaning apparatus to clean a work including a plurality of chips arrayed on a surface of a sheet-like carrier with gaps formed therebetween, the cleaning apparatus comprising:
a holder which holds the work in such a posture that principal surfaces of the chips are inclined with respect to a horizontal plane;
a positioning mechanism which positions the work in a predetermined posture by rotating the work held by the holder about an axis of rotation along a normal direction to the principal surfaces; and
a nozzle which is arranged above the work and discharges a cleaning liquid toward the work.

2. The cleaning apparatus according to claim 1, wherein the positioning mechanism is configured to position the work such that grooves between the chips formed in gaps extend along a plane parallel to the normal direction and a vertical direction.

3. The cleaning apparatus according to claim 2 to clean the work in which a plurality of chips are two-dimensionally arrayed in two array directions intersecting each other, wherein:
the positioning mechanism positions the work in a first posture in which the grooves formed along a first direction, out of the two array directions, extend along the plane, and then rotates and positions the work in a second posture in which the grooves formed along a second direction, out of the two array directions, extend along the plane; and
the nozzle discharges the cleaning liquid in each of a state where the work is positioned in the first posture and a state where the work is positioned in the second posture.

4. The cleaning apparatus according to claim 3, wherein the nozzle continuously discharges the cleaning liquid while the posture of the work is changed from the first posture to the second posture.

5. The cleaning apparatus according to claim 2, wherein the nozzle is provided with a plurality of discharge ports corresponding to each of the plurality of grooves and discharging the cleaning liquid.

6. The cleaning apparatus according to claim 1, wherein the holder includes:
a holding member having a work placement surface on which the work is to be placed;
a chuck mechanism which fixes the work to the work placement surface; and
an inclination adjusting mechanism which displaces the holding member between a horizontal posture and an inclined posture.

7. A cleaning method for cleaning a work including a plurality of chips arrayed on a surface of a sheet-like carrier with gaps formed therebetween, the cleaning method comprising:
holding the work such that principal surfaces of the chips are inclined with respect to a horizontal plane and grooves between the chips formed in the gaps extend along a plane parallel to a normal direction to the principal surfaces and a vertical direction; and
arranging a nozzle above the work and discharging a cleaning liquid from the nozzle toward the work.

8. The cleaning method according to claim 7 for cleaning the work in which a plurality of chips are two-dimensionally arrayed in two array directions intersecting each other, wherein:
the work is positioned in a first posture in which the grooves formed along a first direction, out of the two array directions, extend along the plane and the cleaning liquid is discharged from the nozzle to the work;
the work is rotated and positioned in a second posture in which the grooves formed along a second direction, out of the two array directions, extend along the plane; and
the cleaning liquid is discharged in each of a state where the work is positioned in the first posture and a state where the work is positioned in the second posture.
